(19) United States
(12) Patent Application Publication
(10) Pub. No.: US 2012/0104374 A1
(43) Pub. Date: May 3, 2012

(54) COATING COMPOSITIONS FOR FORMING NANOCOMPOSITE FILMS

(75) Inventor: Pierre-Marc Allemand, San Jose, CA (US)

(73) Assignee: CAMBRIOS TECHNOLOGIES CORPORATION, Sunnyvale, CA (US)

(21) Appl. No.: 13/286,437

(22) Filed: Nov. 1, 2011

Related U.S. Application Data
(60) Provisional application No. 61/409,821, filed on Nov. 3, 2010.

(51) Int. Cl. H01L 51/54; B32B 15/04; B05D 5/12; H01B 1/22; B82Y 99/00

(52) U.S. Cl. 257/40; 427/123; 427/125; 252/512; 252/514; 428/457; 977/952; 257/E51.024

(57) ABSTRACT

Described herein are coating compositions comprising metal nanostructures and one or more conductive polymers, and nanocomposite films formed thereof.

### BACKGROUND

1. Technical Field

This disclosure is related to coating compositions suitable for forming composite transparent conductive coatings or films.

2. Description of the Related Art

Coating compositions comprising conductive nanowires can be coated on a wide range of rigid and flexible substrates to provide transparent conductive thin films or coatings. When suitably patterned, nanowire-based transparent conductors are used as transparent electrodes or thin film transistors in flat panel electrochromic displays such as liquid crystal displays (LCD), plasma displays, touch panels, electroluminescent devices such as organic light emitting diode (OLED), thin film photovoltaic cells (PV), and the like. Other applications of the nanowire-based transparent conductors include anti-static layers and electromagnetic wave shielding layers.

In particular, nanowire-based coating compositions are suited for printed electronics, an alternative technology to the conventional chip-based manufacture of electrical or electronic components. Using a solution-based format, printed electronic technology makes it possible to produce robust electronics on large-area, flexible substrates. In particular, conventional printing processes such as continuous roll-to-roll printing can be adopted in printed electronics to further reduce manufacturing cost and improve throughput.

Co-pending and co-owned U.S. patent application Ser. Nos. 11/504,822, 11/766,552, 11/871,767, 11/871,721, 12/380,293, 12/773,734, and 12/380,294 describe various approaches for synthesizing conductive nanowires (e.g., silver nanowires), and preparing conductive films via a number of coating or printing methods. These applications are incorporated herein by reference in their entireties.

### SUMMARY OF INVENTION

Described herein are stable coating compositions containing a plurality of metal nanostructures and one or more conductive polymers as well as a process for making a nanocomposite coating on various substrates. The nanocomposite coating is typically a transparent conductive coating that is particularly useful as a conductive component in opto-electrical devices such as LCD and LCD insulated panel system (IPS), as well as OLED and PV devices.

Thus, one embodiment provides a coating composition comprising: a plurality of metal nanostructures; one or more conductive polymers; and a liquid carrier.

In various further embodiments, the coating composition comprises silver nanowires, and the one or more conductive polymers are PEDOT:PSS.

In various further embodiments, the liquid carrier is an aqueous solvent system. In other embodiments, the liquid carrier is non-aqueous and includes one or more alcohols.

In various further embodiments, the coating composition includes 0.1%-4%, 0.1%-1.5%, 0.1%-1%, or 1%-4% metal nanostructures by weight of the coating composition.

In various further embodiments, the one or more conductive polymers are of 0.1%-1%, or 1%-3%, or 2%-5%, or 3%-10%, or 8%-10% by weight of the coating composition.

In further embodiments, the plurality of metal nanostructures and the one or more conductive polymers are in a weight ratio of 1:1, 1:2, 1:3, 1:4, or 1:5.

In yet another embodiment, the coating composition further comprises a plurality of light-scattering particles.

Another embodiment provides a device, comprising a composite film having: a conductive film of one or more conductive polymers; and a plurality of metal nanostructures, wherein the plurality of metal nanostructures are randomly distributed in the one or more conductive polymers.

In various further embodiments, the device further comprises a first electrode; a second electrode; and an organic light-emitting layer disposed between the first electrode and the second electrode, wherein the composite film is a charge injection layer disposed between the organic light-emitting layer and one of the first electrode and the second electrode.

In various further embodiments, the composite film comprises silver nanowires embedded in PEDOT:PSS.

In various further embodiments, the composite film has a sheet resistance of less than 200 ohms/sq and a light transmission higher than 85%.

A further embodiment provides a method comprising: providing a coating composition including a plurality of metal nanostructures, one or more conductive polymers, and a liquid carrier; forming a single coat of the coating composition on a substrate; and forming a composite film including the plurality of metal nanostructures embedded in the conductive polymer by allowing the single coat to cure.

In various further embodiments, forming the single coat comprises spin-coating or direct printing the coating composition on the substrate.

### BRIEF DESCRIPTION OF THE SEVERAL VIEWS OF THE DRAWINGS

In the drawings, identical reference numbers identify similar elements or acts. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements as drawn are not intended to convey any information regarding the actual shape of the particular elements, and have been selected solely for ease of recognition in the drawings.

FIG. 1 schematically shows an OLED in accordance with an embodiment of this disclosure.

FIG. 2 is a dark field view of a composite conductive film according to one embodiment.

FIG. 3 is, as a comparison, a dark field view of a transparent conductor of silver nanowires in a non-conductive binder.

FIG. 4 shows an etched composite conductive film according to another embodiment.

FIG. 5 shows a composite conductive film according to another embodiment.

### DETAILED DESCRIPTION OF THE INVENTION

Described herein are stable coating compositions containing a plurality of metal nanostructures and one or more conductive polymers and methods of making the same. The coating composition can be deposited on various substrates by wet chemical methods to provide conductive composite films of metal nanostructures and conductive polymer. The metal nanostructures are embedded or distributed in the conductive polymer and both contribute to the overall electrical and optical properties of the composite film. In addition, the composite films have desirable charge injection properties and environment stability.

According to certain embodiments, the coating composition (also referred to as “coating formulations,” “ink” or “ink formulations”) comprises a plurality of metal nanostructures, one or more conductive polymers and a liquid carrier.

In various embodiments, the metal nanostructures include metal nanowires, and in particular, silver nanowires. At least one dimension (the diameter) of the nanowires is less than 1000 nm, and more typically, less than 500 nm, and more typically, less than 100 nm. The metal nanostructures can be prepared according to co-pending, co-owned U.S. patent application Ser. Nos. 11/504,822, 11/766,552, 12/862,664, and 12/868,511. In certain embodiments, the metal nanostructures comprise silver nanowires (with an aspect ratio of more than 10, or more typically, more than 100).

Conductive polymers are polymers that are characterized by electronic delocalization throughout a conjugated backbone of continuous overlapping orbitals. For example, polymers formed of alternating single and double carbon-carbon bonds can provide a continuous path of overlapping p orbitals which electrons can occupy.

Common classes of organic conductive polymers include, without limitation, poly(acetylene)s, poly(pyrrole)s, poly(thiophene)s, poly(aniline)s, poly(fluorene)s, poly(3-alkylthiophene)s, poly(3,4-ethylenedioxythiophene), also known as PEDOT, polytetrathiafulvalenes, polynaphthalenes, polyparaphenylene, poly(paraphenylene sulfide), and poly(paraphenylene vinylene)s.

In certain embodiments, the conductive polymer may be combined or doped with one or more charged polymers. In one embodiment, the conductive polymer is poly(3,4-ethylenedioxythiophene):poly(styrenesulfonate), also known as PEDOT:PSS. Commercially available PEDOT:PSS may be obtained under the trade name Clevios™ (Heraeus Clevios GmbH, Germany).

Both the conductive polymer and the metal nanostructures contribute to the overall conductivity of the composite film. Thus, the contents of the conductive polymer and metal nanostructures in the coating composition determine the connectivity between the metal nanowires and the film-forming of the conductive polymer.

In certain embodiments, the conductive polymer is present in the coating composition at an amount of 0.1%-10% by weight of the coating composition. In particular embodiments, the conductive polymer is the coating composition may be in the range of 0.1%-1%, or 1%-3%, or 2%-5%, or 3%-10%, or 8%-10%.

In certain embodiments, the metal nanostructures are present in the coating composition at an amount of 0.05%-5% by weight of the coating composition. In particular embodiments, the coating composition may have a silver content (i.e., a total weight of the silver nanostructures) in the range of 0.1%-4%, 0.1%-1.5%, 0.1%-1%, or 1%-4%.

In certain embodiments, the weight ratio of the metal nanostructures and the conductive polymer is in the range of 5:1 to 1:5. In preferred embodiments, the weight ratio of the metal nanostructures and the conductive polymer is about 1:1, 1:2, 1:3, 1:4, or 1:5.

Typically, the liquid carrier can be a single solvent or a combination of two or more miscible solvents.

In certain embodiments, the liquid carrier is water.

In other embodiments, the liquid carrier is an aqueous solvent system that comprises water and one or more co-solvents. The co-solvent is miscible with water (hydrophilic). In certain embodiments, the co-solvent is an alcohol. Suitable alcoholic co-solvents include, for example, methanol, ethanol, n-propanol, i-propanol (IPA), n-butanol, i-butanol, t-butanol and the like. Polyols such as propylene glycol and ethylene glycol are also suitable alcoholic co-solvents.

In certain embodiments, the water comprises up to 100%, up to 80%, up to 75%, up to 70%, up to 65%, up to 60%, up to 55%, up to 50%, up to 45%, up to 40%, up to 35%, up to 30% (by weight) of the aqueous solvent system.

In another embodiment, the liquid carrier is non-aqueous and comprises one or more organic solvents. Typically, the organic solvents include one or more alcohols. Suitable alcoholic solvents include, for example, methanol, ethanol, n-propanol, i-propanol (IPA), n-butanol, i-butanol, t-butanol, propylene glycol monomethyl ether and polyols such as propylene glycol and ethylene glycol.

The coating composition may further include one or more agents that serve to stabilize the coating composition, and facilitate the film forming process following deposition on a substrate. These agents are typically non-volatile and include surfactants, viscosity modifiers, corrosion inhibitors and the like.

In certain embodiments, the coating composition may further include one or more surfactants, which serve to adjust the surface tension and wetting. Representative examples of suitable surfactants include fluorosurfactants such as ZONYL® surfactants, including ZONYL® FSN, ZONYL® FSO, ZONYL® FSA, ZONYL® FSH (DuPont Chemicals, Wilmington, Del.), and NOVEC™ (3M, St. Paul, Minn.). Other exemplary surfactants include non-ionic surfactants based on alkylphenol ethoxylates. Preferred surfactants include, for example, octylphenol ethoxylates such as TRITON™ (x100, x114, x45), and secondary alcohol ethoxylates such as TERGITOL™ 15-S series (Dow Chemical Company, Midland Mich.). Further exemplary non-ionic surfactants include acetylenic-based surfactants such as DYNOL® (604, 607) (Air Products and Chemicals, Inc., Allentown, Pa.) and n-dodecyl β-D-maltoside.

In certain embodiments, the coating composition may further include one or more viscosity modifiers, which serve as a binder that immobilizes the nanostructures on a substrate. Examples of suitable viscosity modifiers include hydroxypropyl methylcellulose (HPMC), methyl cellulose, ethyl cellulose, xanthan gum, polyvinyl alcohol, carboxy methyl cellulose, and hydroxy ethyl cellulose.

In certain embodiments, the ink composition may further include one or more additives that improve the overall performance and stability of the ink composition. For instance, the additives may include adhesion promoters such as organosilanes, including 3-glycidoxypropyltrimethoxysilane, sold as Z-6040 (Dow Corning); antioxidants such as citric acid, gallate esters, tocopherols, and other phenolic antioxidants; UV absorbers such as Uvinul® 3000 (BASF), used alone or in combination with HALS (hindered amines light stabilizers); corrosion inhibitors to protect the metallic nanostructures from corrosion, or a combination thereof. Examples of specific corrosion inhibitors are described in co-pending U.S. application Ser. No. 11/504,822.

In a preferred embodiment, the coating composition is pH neutral (i.e., pH=7±0.25). In certain embodiments, for instance, the acidity of the conductive polymer PEDOT:PSS may be neutralized by introducing a mild base such as ammonia into the coating composition.

In other embodiments, the coating composition is alkaline (e.g., pH>7). In one embodiment, the pH of the coating composition is about 10.

In certain embodiments, the coating composition may further comprise a light-scattering material. As used herein, “light-scattering material” refers to an inert material that causes light scattering. The light-scattering material includes, for example, particulate scattering media or scattering-promoting agents (e.g., precursors). In certain embodiments, the light-scattering material is in the form of particles, also referred to as “light-scattering particles,” which can be directly incorporated into a coating solution of polyimide. Following coating of the coating composition on the substrate, the light-scattering particles are distributed randomly in the conductive polymer matrix. The light-scattering particles are preferably micro-sized particles, or more preferably nano-sized particles. Additional description of the light-scattering materials can be found in Published U.S. Patent Application No. 2011/0163403, which is incorporated herein by reference in its entirety.

The coating composition can be coated on any substrate by methods known in the art (e.g., spin coating, or direct printing such as jet printing, screen printing, gravure printing, flexographic printing or reverse offset printing, etc.). In particular, the coating composition allows for the formation of a composite film in a single coat. Thus, one embodiment provides a method comprising: providing a coating composition including a plurality of metal nanostructures, one or more conductive polymers, and a liquid carrier; forming a single coat of the coating composition on a substrate; and curing the single coat to provide a composite film including the plurality of metal nanostructures embedded in the conductive polymer.

The resulting composite film (also referred to as a “nanocomposite” film) comprises a conductive polymer doped with metal nanostructures at the same weight ratio that corresponds to their weight ratio in the coating composition. In addition to imparting electrical conductivity, the conductive polymer also serves as a binder or a matrix that immobilizes the metal nanostructures.

Depending on the content of the metal nanostructures in the coating composition, the metal nanostructures in the composite film may or may not reach an electrical percolation threshold, above which long range connectivity of the metal nanostructures can be achieved. However, in an embodiment in which the metal nanostructures are below the percolation threshold, the composition film may still have satisfactory conductivity due to the presence of the conductive polymer film. In other embodiments, the metal nanostructures are at or above the percolation threshold.

The electrical conductivity of the nanocomposite film is measured by “sheet resistance,” which is represented by ohms/square (or “ohms/sq”). The sheet resistance is a function of at least the surface loading density, the size/shapes of the nanostructures, and the intrinsic electrical property of the nanostructure constituents. As used herein, a thin film is considered conductive if it has a sheet resistance of no higher than 10⁸ ohms/sq. Preferably, the sheet resistance is no higher than 10⁴ ohms/sq, 3,000 ohms/sq, 1,000 ohms/sq or 350 ohms/sq, or 100 ohms/sq. Typically, the sheet resistance of a conductive network formed by metal nanostructures is in the ranges of from 10 ohms/sq to 1000 ohms/sq, from 100 ohms/sq to 750 ohms/sq, 50 ohms/sq to 200 ohms/sq, from 100 ohms/sq to 500 ohms/sq, or from 100 ohms/sq to 250 ohms/sq, or 10 ohms/sq to 200 ohms/sq, from 10 ohms/sq to 50 ohms/sq, or from 1 ohms/sq to 10 ohms/sq. Typically, the workable range of the sheet resistance for opto-electrical devices (e.g., OLED, PV) is less than 200 ohms/sq. More preferably, the sheet resistance is less than 20 ohms/square, or less than 15 ohms/square, or less than 10 ohms/square.

Optically, the nanostructure-based transparent conductors have high light transmission in the visible region (400 nm-700 nm). Typically, the transparent conductor is considered optically clear when the light transmission is more than 70%, or more typically more than 85% in the visible region. More preferably, the light transmission is more than 90%, more than 93%, or more than 95%. As used herein, unless specified otherwise, a conductive film is optically transparent (e.g., more than 70% in transmission). Thus, transparent conductor, transparent conductive film, layer or coating, conductive film, layer or coating, and transparent electrode are used interchangeably.

Haze is an index of optical clarity. Haze results from light-scattering and reflection/refraction due to both bulk and surface roughness effects. For certain opto-electrical devices such as PV cells and OLED lighting applications, high-haze transparent conductors may be preferred. These transparent conductors typically have haze values of more than 10%, more typically more than 15%, or more typically, in the range of 20%-50%. See Published U.S. Patent Application No. 2011/0163403. For other devices such as OLED for display applications, low-haze is preferred. Additional details for adjusting or reducing haze can be found, for example, Published U.S. Patent Application No. 2009/0321113. These published U.S. patent applications are co-pending applications assigned to Cambrios Technologies Inc., the assignee of the present disclosure.

In various embodiments, the nanocomposite film has the following characteristics:

thickness: 10 nm-300 nm;

optical transmission: 80%-99%;

haze: 0.1%-10%, preferably less than 3%;

conductivity: 1 ohm/sq-1000 ohms/sq, or 5 ohms/sq-300 ohms/sq, or 20 ohms/sq-200 ohms/sq, preferably less than 50 ohms/sq.

The coating composition may be coated on any substrate, rigid or flexible. Preferably, the substrate is also optically clear, i.e., light transmission of the material is at least 80% in the visible region (400 nm-700 nm).

Examples of flexible substrates include, but are not limited to: polyesters (e.g., polyethylene terephthalate (PET), polyester naphthalate, and polycarbonate), polyolefins (e.g., linear, branched, and cyclic polyolefins), polyvinyls (e.g., polyvinyl chloride, polyvinylidene chloride, polyvinyl acetals, polystyrene, polyacrylates, and the like), cellulose ester bases (e.g., cellulose triacetate, and cellulose acetate), polysulphones such as polyethersulphone, polyimides, silicones, and other conventional polymeric films.

Examples of rigid substrates include glass, polycarbonates, acrylics, and the like. In particular, specialty glass such as alkali-free glass (e.g., borosilicate), low alkali glass, and zero-expansion glass-ceramic can be used. The specialty glass is particularly suited for thin panel display systems, including Liquid Crystal Display (LCD).

In a further embodiment, the composite film may further include an inert layer of overcoat which provides stability and protection. The overcoat can also provide favorable optical properties, such as anti-glare and anti-reflective properties, which serve to further reduce the reflectivity of the nanoparticles.

Thus, the overcoat can be one or more of a hard coat, an anti-reflective layer, a protective film, a barrier layer, and the like, all of which are extensively discussed in co-pending application Ser. Nos. 11/871,767 and 11/504,822. Examples of suitable hard coats include synthetic polymers such as polyacrylics, epoxy, polyurethanes, polysilanes, silicones, poly(silico-acrylic) and so on. Suitable anti-glare materials are well known in the art, including without limitation, siloxanes, polystyrene/PMMA blend, lacquer (e.g., butyl acetate/nitrocellulose/wax/alkyd resin), polythiophenes, polypyrroles, polyurethane, nitrocellulose, and acrylates, all of which may comprise a light diffusing material such as colloidal or fumed silica. Examples of protective film include, but are not limited to: polyester, polyethylene terephthalate (PET), polybutylene terephthalate, polymethyl methacrylate (PMMA), acrylic resin, polycarbonate (PC), polystyrene, triacetate (TAO), polyvinyl alcohol, polyvinyl chloride, polyvinylidene chloride, polyethylene, ethylene-vinyl acetate copolymers, polyvinyl butyral, metal ion-crosslinked ethylene-methacrylic acid copolymers, polyurethane, cellophane, polyolefins or the like; particularly preferable are PET, PC, PMMA, or TAO.

As discussed herein, the coating composition may be deposited on a substrate to form a nanocomposite film that includes one or more conductive polymers embedded or doped with metal nanostructures. In one embodiment, the nanocomposite film may be a charge injector layer in an OLED device. More specifically, referring to FIG. 1, a device (10) comprises a substrate (20), a first electrode disposed on the substrate (30), a charge injection layer (40) disposed on the first electrode (30), the charge injection layer being a composite film formed by depositing a coating composition comprising a plurality of metal nanowires and one or more conductive polymers, a light emitting layer (50) disposed on the charge injection layer (40) and a second electrode (60) disposed on the light emitting layer (50). The charge injection layer (40) is formed by depositing a coating composition as described herein. As discussed, the coating can be carried out by spin coating or printing. In various embodiments, the charge injection layer has a thickness in the range of 10 nm-300 nm; optical transmission in the range of 80%-99%; haze in the range of 0.1%-10%, preferably less than 3%; and conductivity in the range of 1 ohm/sq-1000 ohms/sq, preferably less than 50 ohms/sq.

Typically, the first electrode (30) is an anode that is transparent to allow light transmission. The anode can be, for example, a transparent conductor. Examples of suitable transparent conductors include those described in network co-pending, co-owned application Nos. U.S. patent application Ser. Nos. 11/504,822, 12/106,193, and 12/106,244, which applications are incorporated herein by reference in their entireties. Alternatively, the first electrode can be an ITO layer, or a transparent conductive layer comprising carbon nanotubes.

The second electrode (60) is a cathode and may be any suitable material or combination of materials known to the art. The cathode is capable of conducting electrons and injecting them into the light emitting layer (50). Cathode (60) may be transparent or opaque, and may be reflective. Metals and metal oxides are examples of suitable cathode materials.

The light emitting layer (50) can be an organic material capable of emitting light when a current is passed between the first electrode (30) and the second electrode (60). Preferably, the light emitting layer contains a phosphorescent emissive material, although fluorescent emissive materials may also be used. Phosphorescent materials are preferred because of the higher luminescent efficiencies associated with such materials. The light emitting layer may also comprise a host material capable of transporting electrons and/or holes, doped with an emissive material that may trap electrons, holes, and/or excitons, such that excitons relax from the emissive material via a photoemissive mechanism. The light emitting layer may comprise a single material that combines transport and emissive properties.

The various embodiments described herein are further illustrated by the following non-limiting examples.

### EXAMPLE 1

To 2 g of Agfa Orgacon® neutral grade (1.2% of PEDOT:PSS, pH 7) was added 0.4 g of a 1.74% silver nanostructure suspension in water. The resulting dark blue-grey mixture was spun on 2×2 glass at 2500 rpm for 60 seconds and then baked at 140° C. on a hot plate for 90 seconds. The resulting nanocomposite film demonstrated the following properties:

light transmission: 86.4%

haze: 1.73%

sheet resistance: 32 ohms/sq.

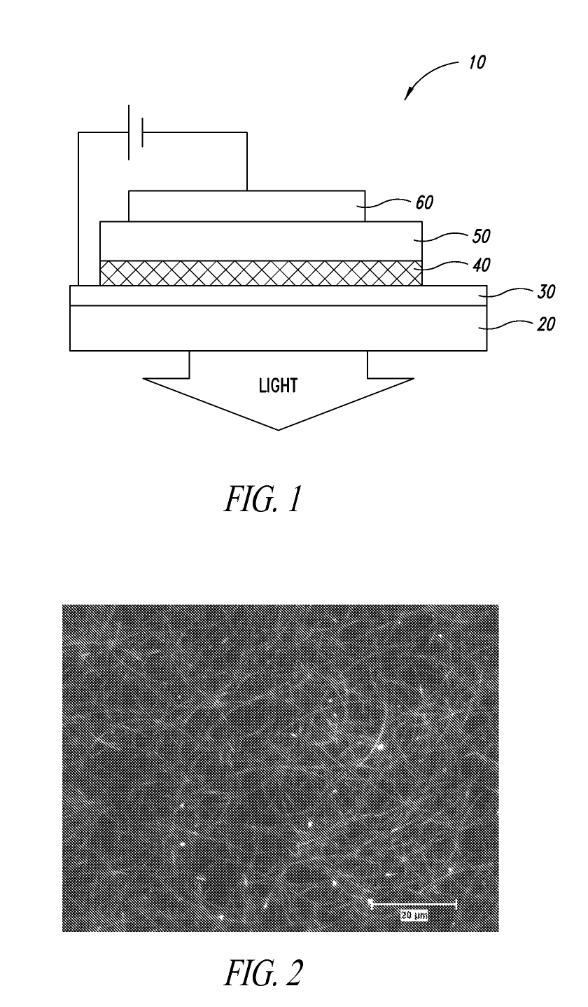

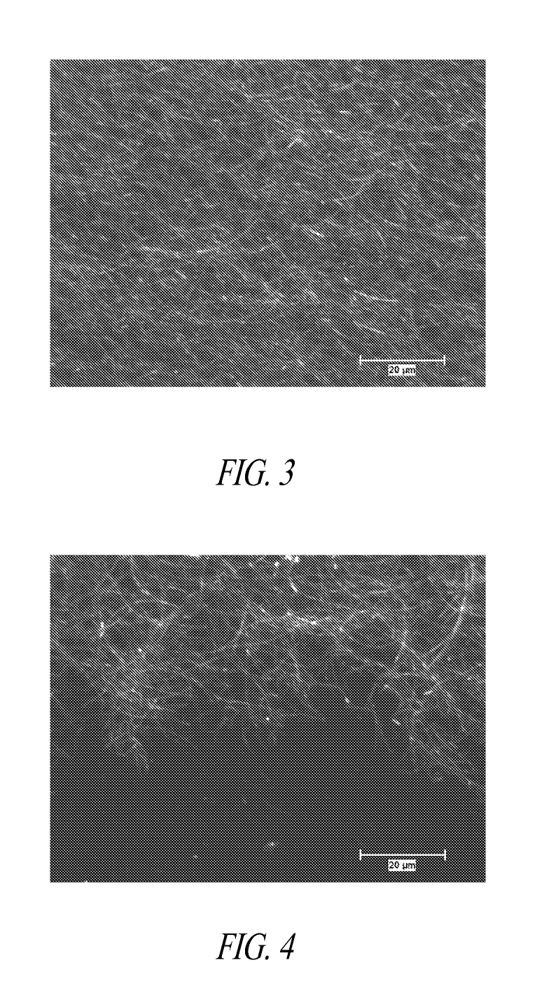

FIG. 2 shows a micrograph at 100× dark field showing uniform nanowire distribution across the glass substrate and within the PEDOT organic matrix. In appearance, the composite resembles conductive films made from coating compositions comprising non-conductive polymer binders such as HPMC (FIG. 3).

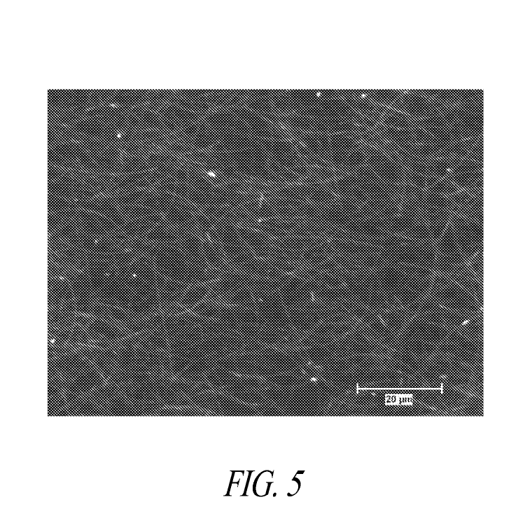

In contrast to nanowire coating formulations using HPMC as a viscosity modifier or binder, the nanocomposite films of nanowires and conductive polymer were found to be easily etched with water, as shown in FIG. 4.

This film was placed in a convection oven at 100° C., and the resistivity was monitored. The film became non-conductive after about 116 hours.

### EXAMPLE 2

A composite film was prepared using the same coating composition as Example 1 that was one-day old. The film demonstrated the following properties, which are comparable to those of the film prepared from a fresh coating composition:

light transmission: 86.9%

haze: 1.61%

sheet resistance: 35 ohms/sq.

A solution of EPON® SU-8 epoxy in propylene glycol monomethyl ether acetate (PGMEA) was spun at 2500 rpm for 60 seconds and thermally cured at 100° C. to form a thin epoxy film of about 318 nm thick on a top surface of the nanowire/PEDOT composite film without dissolving the organic matrix. This epoxy film or top coat would provide the nanowire/PEDOT composite film with certain degrees of protection against atmospheric elements and pollutants, thus mimicking a configuration commonly used in OLED/PV devices. The protected film was then placed in an oven at 100° C., and the resistivity monitored. The resistivity increased by 17% after 522 hours, demonstrating good thermal stability.

### EXAMPLE 3

Another film was made after 16 days, using the same formulation as Example 1 (i.e., the coating composition was 16-days old). The film showed the same properties as those shown in Examples 1 and 2, thus demonstrating that the shelf life of the silver nanowire/PEDOT coating composition is satisfactory.

light transmission: 86.9%

haze: 1.52%

sheet resistance: 39 ohms/sq.

### EXAMPLE 4

Acidic Baytron® P (PEDOT:PSS, pH=2) was neutralized according to US 2007/0077451 A1. More specifically, to 5 g of Clevios™ P was added about 0.125 g of 28% aqueous ammonia dropwise with gentle shaking, until the pH increased from about 2 to about 10. This PEDOT:PSS:NH₃ suspension was then filtered on a 1.5 μm glass fiber filter. Then, about 0.75 g of a 1.74% NWs suspension in water was added to the filtrate with gentle shaking. The resulting dark blue-grey mixture was spun on 2×2 glass at 2500 rpm for 60 seconds and then baked at 140° C. on a hot plate for 90 seconds.

The resulting film (FIG. 5) showed the following properties:

light transmission: 86.7%

haze: 1.11%

sheet resistance: 54 ohms/sq.

As in Example 2, a solution of SU8 epoxy in PGMEA was spun at 2500 rpm for 60 seconds and thermally cured at 100° C., so that a thin epoxy film was formed on top of the NWs/PEDOT composite film. This protected film was placed in an oven at 100° C., and the resistivity monitored. The resistivity increased 20% after 165 hours, demonstrating acceptable thermal stability.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. A coating composition comprising:
a plurality of metal nanostructures;
one or more conductive polymers; and
a liquid carrier.

2. The coating composition of claim 1 wherein the metal nanostructures include silver nanowires.

3. The coating composition of claim 1 wherein the one or more conductive polymers are PEDOT:PSS.

4. The coating composition of claim 1 wherein the liquid carrier is an aqueous solvent system.

5. The coating composition of claim 1 wherein the liquid carrier is non-aqueous and includes one or more alcohols.

6. The coating composition of claim 1 wherein the plurality of metal nanostructures are of 0.1%-4%, 0.1%-1.5%, 0.1%-1%, or 1%-4% by weight of the coating composition.

7. The coating composition of claim 1 wherein the one or more conductive polymers are of 0.1%-1%, or 1%-3%, or 2%-5%, or 3%-10%, or 8%-10% by weight of the coating composition.

8. The coating composition of claim 1, wherein the plurality of metal nanostructures and the one or more conductive polymers are in a weight ratio of 1:1, 1:2, 1:3, 1:4, or 1:5.

9. The coating composition of claim 1 further comprising a plurality of light-scattering particles.

10. A device comprising:
a composite film having:
a conductive film of one or more conductive polymers; and
a plurality of metal nanostructures;
wherein the plurality of metal nanostructures are randomly distributed in the one or more conductive polymers.

11. The device of claim 10 further comprising:
a first electrode;
a second electrode; and
an organic light-emitting layer disposed between the first electrode and the second electrode,
wherein the composite film is a charge injection layer disposed between the organic light-emitting layer and one of the first electrode and the second electrode.

12. The device of claim 10 wherein the composite film comprises silver nanowires embedded in PEDOT:PSS.

13. The device of claim 10 wherein the composite film has a sheet resistance of less than 200 ohms/sq and a light transmission higher than 85%.

14. A method comprising:
providing a coating composition including a plurality of metal nanostructures, one or more conductive polymers, and a liquid carrier;
forming a single coat of the coating composition on a substrate; and
forming a composite film including the plurality of metal nanostructures embedded in the conductive polymer by allowing the single coat to cure.

15. The method of claim 14 wherein forming the single coat comprises spin-coating or direct printing the coating composition on the substrate.

16. The method of claim 14 wherein the coating composition comprises silver nanostructures and PEDOT:PSS.
